(19) United States
(12) Patent Application Publication
(10) Pub. No.: US 2021/0362382 A1
(43) Pub. Date: Nov. 25, 2021

(54) RESIN MOLDING DEVICE

(71) Applicant: APIC YAMADA CORPORATION, Nagano (JP)

(72) Inventors: Masahiko FUJISAWA, Nagano (JP); Hirofumi SAITO, Nagano (JP)

(73) Assignee: APIC YAMADA CORPORATION, Nagano (JP)

(21) Appl. No.: 17/238,135

(22) Filed: Apr. 22, 2021

(30) Foreign Application Priority Data
May 22, 2020 (JP) 2020-089927

(51) Int. Cl. B29C 43/58; H01L 21/67; H01L 21/68; B29C 43/18; B29C 43/36

(52) U.S. Cl. CPC B29C 43/58; H01L 21/67126; H01L 21/681; B29L 2031/34; B29C 43/36; B29C 2043/5833; B29C 43/18

(57) ABSTRACT

A resin molding device that can hold a thin and large-size workpiece without positional displacement when the workpiece is conveyed even if dimensional tolerance and rigidity are different, and can convey the workpiece to a mold frame without losing flatness or damage is provided.

When a loader (4) holds a workpiece (W) aligned by a preheating part (10), a center position of a loader hand (4b) is aligned with a center position of the workpiece (W) according to an amount of positional displacement between an external form position of the workpiece (W) and a reference position in the X-Y direction and the workpiece (W) is then held.

### CROSS-REFERENCE TO RELATED APPLICATION

This application claims the priority benefit of Japan Application No. 2020-089927, filed on May 22, 2020. The entirety of the above-mentioned patent application is hereby incorporated by reference herein and made a part of this specification.

### BACKGROUND

### Technical Field

The present invention relates to a resin molding device in which a workpiece in which an electronic component is mounted on a thin plate type carrier is loaded into a mold frame and compressed and molded.

### Description of Related Art

As an example of a thin plate type carrier, a conveyance device that prevents falling due to deflection of a lead frame and performing conveyance to a mold frame has been proposed.

Positioning pins that are disposed to face each other are inserted into positioning holes, retaining pins are fitted into engaging holes, the lead frame is supported from below by a receiving part, and the lead frame does not fall off of the pins (refer to Patent Document 1: Japanese Patent Laid-Open No. 2018-22730).

[Patent Document 1] Japanese Patent Laid-Open No. 2018-22730

The conveyance device shown in Patent Document 1 described above uses a technology in which, when the lead frame that is a workpiece is erected between the positioning pins fitted into the positioning holes and the retaining pins fitted into the engaging holes, the lead frame is supported from below by the receiving part so that it does not fall while it is assumed that it is deflected due to its own weight. In this manner, since positioning holes are provided in a lead frame that is a carrier for a general mold, the lead frame can be positioned with respect to the frame.

Here, for example, when a workpiece in which an electronic component is mounted on a thin and large-size carrier (a copper plate, a glass plate, etc.) of about 500 mm is supplied to a mold frame, since the carrier has very weak rigidity or is a brittle material, it is difficult to provide positioning holes in the first place, elongation during heating is large due to the large size, and it may be difficult to perform positioning with the positioning holes and the positioning pins provided in the frame. Here, for example, it is conceivable to perform positioning with the external form of the workpiece, but since elongation of the workpiece during heating is large, it may be difficult to dispose the workpiece on the frame so that the centers of the workpiece and the frame are aligned.

### SUMMARY

The present invention provides a resin molding device in which, when a thin and large-size workpiece is conveyed, even if dimensional tolerance is large and a coefficient of linear expansion of the workpiece differs, it is possible to hold the workpiece without positional displacement and convey it to a mold frame.

The present invention has the following configuration.

A resin molding device in which a workpiece in which an electronic component is mounted on a carrier is conveyed to a mold frame and molded with a resin, including: a workpiece alignment part that adjusts the orientation of the workpiece held on a stage to a reference position; and a loader hand mechanism that holds the workpiece aligned by the workpiece alignment part and conveys it to the mold frame, wherein the loader hand mechanism includes a loader hand that clamps and holds the workpiece on the stage; a position detection unit that detects positional displacement between an external form position of the workpiece provided in the loader hand and a reference position; and an alignment mechanism that aligns a center position of the loader hand with a center position of the workpiece in the X-Y direction according to an amount of positional displacement detected by the position detection unit.

With the above configuration, when the loader hand mechanism holds the workpiece aligned by the workpiece alignment part, since the center position of the loader hand is aligned with the center position of the workpiece according to the amount of positional displacement between the external form position of the workpiece and the reference position in the X-Y direction and the workpiece is then held, when a thin and large-size workpiece is conveyed, even if dimensional tolerance is large and a coefficient of linear expansion of the workpiece differs, it is possible to hold the workpiece without positional displacement and convey it to a mold frame.

Preferably, the workpiece alignment part presses the workpiece against reference blocks provided in the X-Y direction and adjusts the orientation of the workpiece to the reference position. Thereby, the orientation of the workpiece can be reliably adjusted to the reference position.

The position detection unit may include an imaging camera, may read coordinates of the external form of the workpiece disposed on the stage and detect positional displacement in the X-Y direction from a positioning mark (alignment mark) indicating the reference position, may include a plurality of imaging cameras and detect coordinates at diagonal positions of the external form of the workpiece, and may detect positional displacement in the X-Y direction from a virtual stage center position.

Thereby, when simply the external form of the workpiece is imaged, the loader hand can calculate an amount of positional displacement from the reference position in the X-Y direction and align the center position of the loader hand with the center position of the workpiece in the X-Y direction.

The stage may be a preheating stage that preheats the workpiece. Thereby, even if preheating is performed immediately before the workpiece is loaded into the mold frame, it is possible to hold the workpiece without positional displacement and convey it to a mold frame.

The loader hand may include an annular pressing member that presses an outer circumferential part from an upper surface of the workpiece and a chuck that supports a lower surface of the workpiece with a predetermined clearance with the end of the workpiece, and the pressing member may be controlled so that a pressing force of the workpiece is variable, and the loader hand mechanism conveys the workpiece preheated on the preheating stage, which is clamped between the pressing member and the chuck, to the mold frame.

Thereby, even if the workpiece is preheated on the preheating stage and the amount of warpage differs, the flatness of the workpiece can be maintained by changing the pressing force of the pressing member, and the workpiece can be positioned and held while maintaining the flatness of the workpiece with the loader hand.

### BRIEF DESCRIPTION OF THE DRAWINGS

FIG. 1 is a layout configuration diagram showing an example of a resin molding device.

FIG. 2 is a layout configuration diagram of a workpiece transfer part and a resin supply part.

FIG. 3 is an explanatory diagram showing a configuration example of a resin supply stage.

FIG. 4A and FIG. 4B show a plan view and a front view of a preheating stage.

FIG. 5A to FIG. 5C show a schematic explanatory diagram of a loader hand, and an explanatory diagram illustrating an alignment operation of aligning a center position between a loader hand and a workpiece.

FIG. 6 is a block configuration diagram showing a control system.

FIG. 7 is a flowchart showing a workpiece alignment operation.

### DESCRIPTION OF THE EMBODIMENTS

According to the present invention, it is possible to provide a resin molding device in which, when a thin and large-size workpiece is conveyed, even if dimensional tolerance is large and a coefficient of linear expansion of the workpiece differs, it is possible to hold the workpiece without positional displacement and convey it to a mold frame.

### Overall Configuration

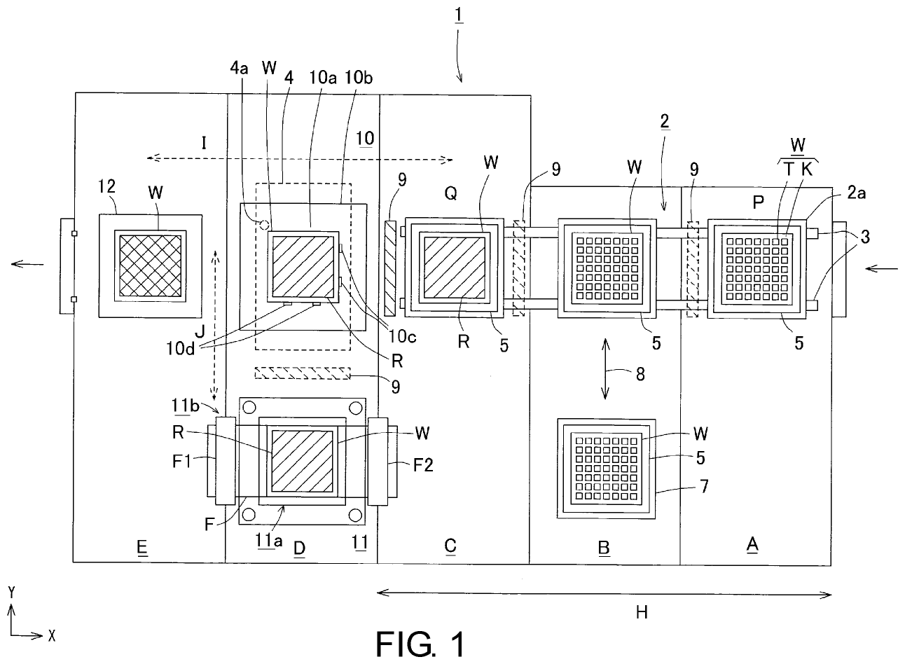

Hereinafter, referring to the drawings, an embodiment of the present invention will be described with reference to FIG. 1. FIG. 1 is a layout configuration diagram of a resin molding device according to an embodiment of the present invention. As the resin molding device, an upper mold cavity type compression molding device 1 is exemplified, and a workpiece W will be described assuming that an electronic component T such as a semiconductor chip is mounted on a thin-plate carrier K (for example, a copper plate, a glass plate, etc.) with a thickness of about 0.2 mm to 3 mm and a size of about 400 mm to 700 mm. As the following device configuration, a device configuration in which a plurality of functional units (units) are linked will be exemplified, but respective functional units may be integrally provided in the device main body. In addition, in all drawings for explaining each embodiment, members having the same function are denoted with the same reference numerals and redundant descriptions thereof may be omitted.

In the compression molding device 1, a workpiece supply unit A, a resin supply unit B, a workpiece delivery unit C, a press unit D, and a cooling unit E are each linked in series. A resin supply stage 7 and a press part 11, which will be described below, are disposed on the front side of the device in consideration of operability and maintenance, and a workpiece transfer part 2 is disposed on the back side of the device.

In the workpiece transfer part 2, a transfer part main body 2a reciprocates between a reception position P and a delivery position Q along a rail part 3 provided between the workpiece supply unit A, the resin supply unit B, and the workpiece delivery unit C (refer to the solid arrow H in FIG. 1). In the workpiece supply unit A, the reception position P at which the workpiece W is received from the previous process is provided. In addition, in the workpiece delivery unit C, the delivery position Q at which the workpiece W is delivered to a loader 4 is provided. The transfer part main body 2a is linked to a conveyor belt by, for example, a conveyor device, and reciprocates. In addition, a holder plate 5 having a sizer larger than and a thickness thicker (for example, about 10 mm) than the external form of the workpiece is mounted on the transfer part main body 2a. The workpiece W that is positioned with respect to and overlaps the holder plate 5 is transferred by the workpiece transfer part 2.

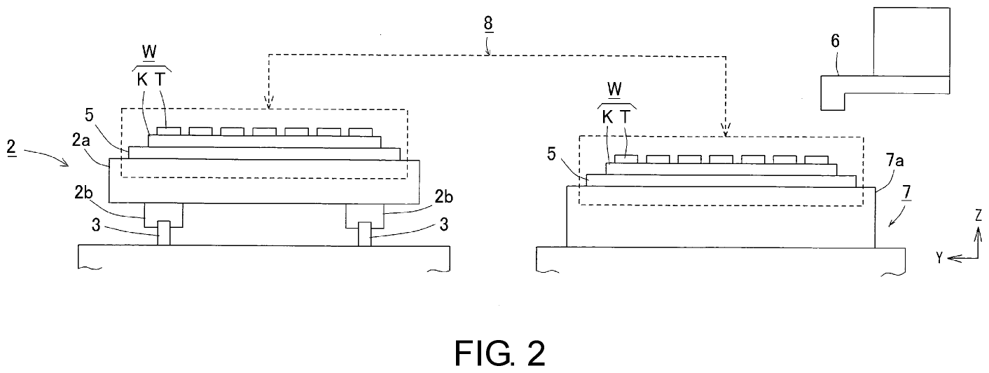

In the resin supply unit B, a dispenser 6 and the resin supply stage 7 through which a granular resin or a liquid resin is supplied is provided. As shown in FIG. 2, the resin supply stage 7 is replaced with a pick and place mechanism 8 that can move in the Y-Z direction while the workpiece W is disposed on the holder plate 5, and a resin R is supplied onto the workpiece W by the dispenser 6. The dispenser 6 is provided so that it is scannable on the workpiece W in the X-Y direction. In the resin supply stage 7, an electronic balance 7a (measuring unit) is provided, and an appropriate amount of a resin is measured and supplied onto the workpiece W.

In the workpiece delivery unit C, the delivery position Q at which the workpiece W onto which the resin R is supplied is delivered to the loader 4 (loader hand mechanism) is provided. In addition, a unit (not shown) that delivers the workpiece W from a delivery position Q to the loader 4 is provided, and the workpiece W is delivered from the holder plate 5 to the loader 4. In the loader 4, as will be described below, an annular pressing member (a frame 4b1) and a plurality of chuck claws are provided and the loader 4 holds the outer circumferential part of the workpiece W in a vertical insertion manner. The workpiece W held at the delivery position Q by the loader 4 while only its outer circumference is clamped to a preheating part 10 (a preheating stage 10b) of the press unit D is conveyed.

In the workpiece delivery unit C, a cleaner device 9 that removes a resin powder and dust such as foreign substances (contaminants) attached to the back surface of the workpiece W is provided. In addition, the cleaner device 9 is cleaned when the back side of the workpiece W onto which a resin held by the loader 4 is supplied is conveyed to the press unit D (preheating part). The cleaner device 9 in which a cleaner head part is divided into a plurality of parts in the width direction is provided so that the height position can be changed. The cleaner device 9 is provided so that it is vertically movable by a servo mechanism (not shown), and can be cleaned by adjusting the height position in order to avoid deflection of the workpiece W held by the loader 4 and interference with a chuck (not shown) of the loader hand.

In the press unit D, the preheating part 10 and the press part 11 are provided. In the preheating part 10, a preheater 10a is provided. The preheater 10a preheats the workpiece W onto which a resin is supplied that is disposed on the preheating stage 10b (workpiece alignment part) to about 100° C.

The press part 11 includes a mold frame 11a having an upper mold and a lower mold. In the present example, the resin and the workpiece W are disposed on the lower mold, the cavity is formed in the upper mold, the mold is closed, and heating is performed to, for example, about 130° C. to 150° C., for compression molding. The lower mold is movable and the upper mold is fixed, but the lower mold may be fixed and the upper mold may be movable, or both molds may be movable. Here, the mold frame 11a is mold-opened and closed by a known mold opening and closing mechanism (not shown). For example, the mold opening and closing mechanism includes a pair of platens, a plurality of link mechanisms (tie bars and pillars) on which the pair of platens are erected, a drive source (for example, an electric motor) for moving (elevating) the platens, a drive transmission mechanism (for example, a toggle link), and the like (the drive mechanism is not shown).

In the mold frame 11a, a release film F is sucked and held on the surface of an upper mold clamp including the upper mold cavity. A film conveyance mechanism 11b is provided on the upper mold. For the release film F, an elongated continuous film material having excellent heat resistance, ease of peeling, flexibility, and extensibility is used, and for example, polytetrafluoroethylene (PTFE), polytetrafluoroethylene polymer (ETFE), PET, FEP, fluorine-impregnated glass cloth, polypropylene, polyvinylidene chloride, and the like are preferably used. The release film F is conveyed through the surface of the upper mold clamp from a feed roller F1 to a winding roller F2 in a winding manner. Here, instead of the elongated film, a strip-shaped film cut to a size required for a strip-shaped mold corresponding to the strip-shaped workpiece W may be used.

The workpiece W preheated to a predetermined temperature by the preheating part 10 is held by the loader 4, and loaded into the opened mold frame 11a. In this case, as will be described below, on the preheating stage 10b (workpiece alignment part), as will be described below, the workpiece W is pressed against a pair of X-axis reference blocks 10c and Y-axis reference blocks 10d with a pusher or the like, and thus the orientation of the workpiece W is adjusted to correct the positional displacement in the direction of rotation. After workpiece alignment is performed, the amount of displacement between the workpiece center position and the stage center position is detected from the amount of positional displacement between the external form position of the workpiece W and an alignment mark on the preheating stage 10b. If a dimensional tolerance of, for example, about ±1 mm is allowed with respect to the external form dimension of the workpiece W, a maximum difference of about 2 mm may occur. In addition, when the workpiece W is preheated to a certain temperature on the preheating stage 10b, the workpiece W is elongated. Here, elongation of the workpiece W due to preheating differs depending on the material of the carrier constituting the workpiece, and since the coefficient of linear expansion differs between various materials that are expected to be used such as resin materials constituting a so-called substrate, metal materials such as copper carriers, and glass (crystal) materials such as glass carriers, the amount of elongation of the workpiece W also differs. Therefore, before loading into the mold frame 11a, preferably, the workpiece holding position of the loader 4 can be corrected regardless of the material of the carrier K.

Here, in the present embodiment, the coordinates of the corner parts of the workpiece W are read by an imaging camera 4a included in the loader 4, the distance (amount of displacement with respect to the alignment mark) in the X-Y direction with respect to the positioning mark (alignment mark) indicating the reference position is calculated, the center position of the loader 4 is aligned with the center position of the workpiece W, and the workpiece W is then held. Here, since the workpiece

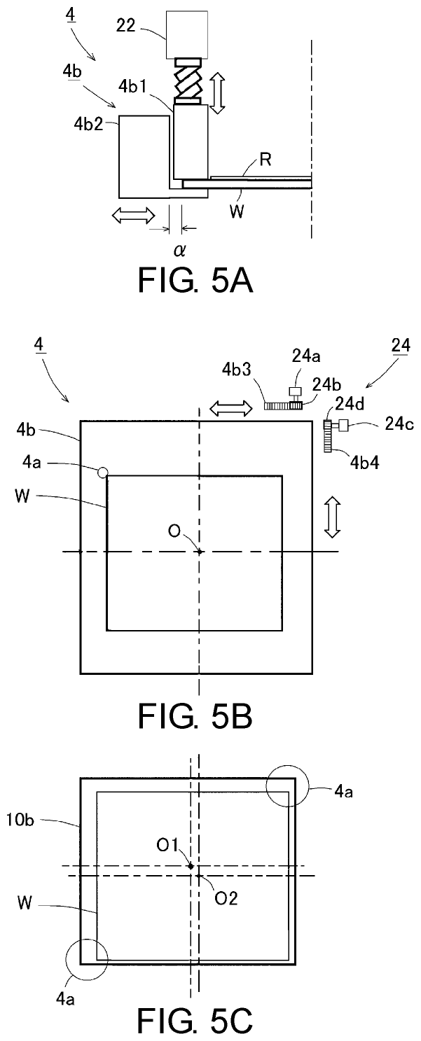

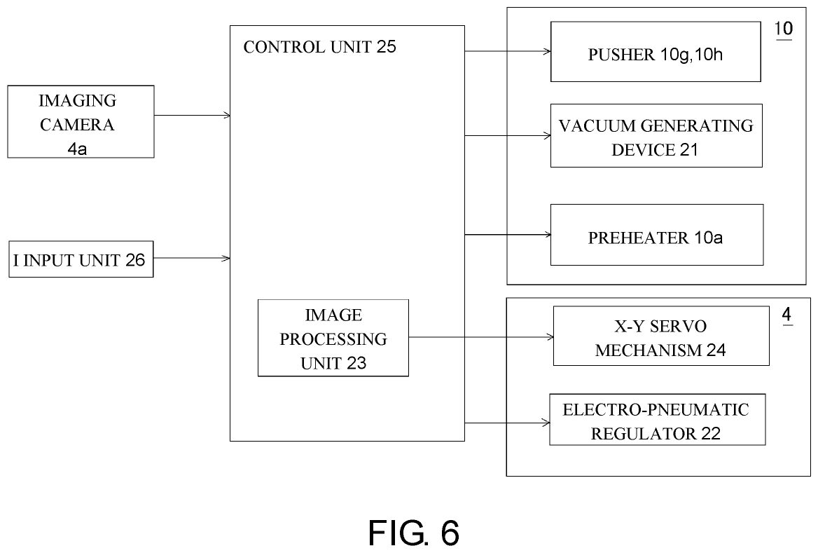

W draws a smile curve whose center is convex downward and tends to warp on the preheating stage 10b, the loader 4 presses the entire circumference of the workpiece W from the upper surface side with an annular pressing member (the frame 4b1: refer to FIG. 5A) while the back side of the workpiece is supported by the multi-point chuck, and holds both surfaces of the workpiece in an insertion manner. The pressing force of the frame 4b1 is controlled by an electro-pneumatic regulator 22 (refer to FIG. 6), the pressing force is variably controlled according to an input signal, and thus warping of the workpiece W that fluctuates due to preheating is minimized. The multi-point chuck of the loader 4 is supported by providing a predetermined clearance with both ends of the workpiece in consideration of expansion and contraction of the workpiece W. The loader 4 is aligned with a lock block (not shown) provided on the lower mold of the mold frame 11a, the workpiece W is delivered to the surface of the lower mold clamp, the workpiece W is sucked and held, the mold frame 11a is closed, and the mold resin is heated and cured. Here, in the preheating stage 10b and the mold frame 11a, relief concave parts for avoiding interference with the chuck when the workpiece W is supported by the loader 4 are provided. In order to reduce the size of the relief concave part, it is preferable that the clearance between the chuck and both ends of the workpiece be as small as possible. Here, the method of holding both surfaces of the workpiece with a loader hand 4b of the loader 4 in an insertion manner can be similarly applied to a mechanism for holding the workpiece W according to the pick and place mechanism 8.

When the resin molding operation is completed, the mold frame 11a is opened, the loader 4 enters the frame, and the workpiece W is held and taken out. The workpiece W that is held by the loader 4 is conveyed to the cooling unit E by the press unit D, and delivered to a cooling stage 12 and cooled. The cooled workpiece W is subjected to a subsequent process (a dicing process, etc.). The movement range of the loader 4 in the X-Y direction is indicated by dashed arrows I and J shown in FIG. 1.

### Workpiece Transfer Part

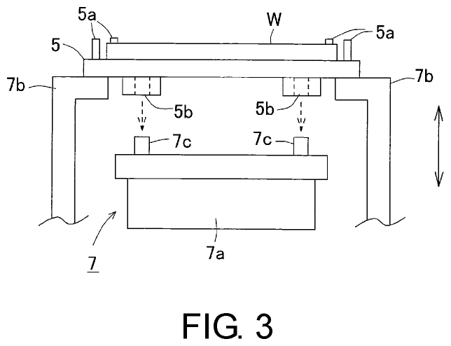

Here, a configuration of the workpiece transfer part 2 will be described with reference to FIG. 2 to FIG. 3. In FIG. 2, the transfer part main body 2a of the workpiece transfer part 2 is supported by the rail part 3 via a linear rail guide 2b.

On the holder plate 5, a positioning member for positioning the workpiece W based on the external form is provided. As an example, on the holder plate 5, a pair of positioning pins 5a for positioning the workpiece W at four corners are provided. The workpiece W is disposed on the upper surface of the holder plate 5 by aligning corners of the workpiece W formed in a rectangular shape between the positioning pins 5a.

Moreover, as shown in FIG. 3, the pick and place mechanism 8 delivers the workpiece W and the holder plate 5 to a lifter device 7b at an elevating position. The lifter device 7b descends while supporting the holder plate 5 and is disposed on the electronic balance 7a by fitting, for example, positioning pins 7c provided at four locations on the upper surface of the electronic balance 7a into, for example, positioning holes 5b provided at four locations at the position corresponding to the holder plate 5.

### Workpiece Alignment Part

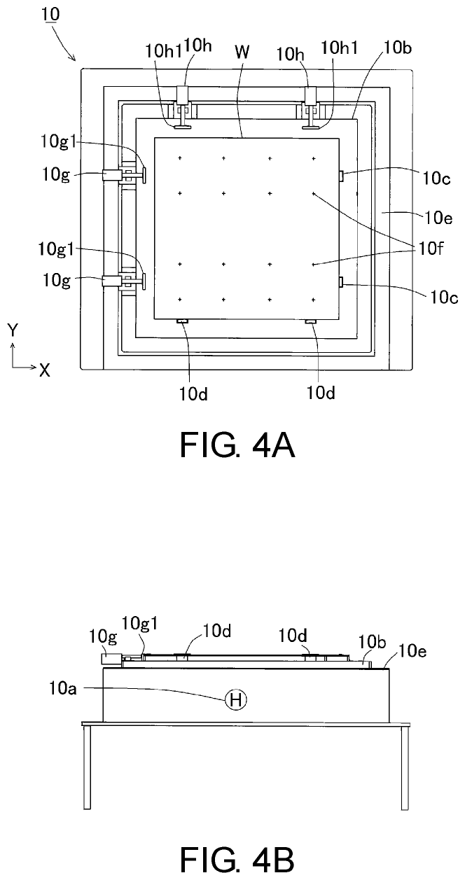

As shown in FIGS. 4A and 4B, in the preheating part 10, the rectangular preheating stage 10b is provided on a heater stand 10e in which the preheater 10a is built. On the preheating stage 10b, a plurality of suction holes 10f on which the workpiece W is mounted and sucked and held are provided. The suction holes 10f are connected to a vacuum generating device 21 to be described below. The preheater 10a preheats the workpiece W and the resin R to about 100° C. Here, the workpiece alignment part is not limited to the preheating part 10, and may be the delivery position Q of the workpiece delivery unit C, the resin supply stage 7, or the like.

In FIG. 4A, the pair of X-axis reference blocks 10c are formed upright along the edge parts of the preheating stage 10b in the Y-axis direction. In addition, the pair of Y-axis reference blocks 10d are formed upright along the edge parts of the preheating stage 10b in the X-axis direction. A pair of X-axis pushers 10g are provided on the edge parts that face the X-axis reference blocks 10c of the preheating stage 10b. A pair of Y-axis pushers 10h are provided on the edge parts that face the Y-axis reference blocks 10d of the preheating stage 10b. For these X-axis pushers 10g and Y-axis pushers 10h, for example, an X-axis air cylinder and a Y-axis air cylinder are used as drive sources. The drive sources are not limited to the air cylinders, but other components such as solenoids may be used. A pressing member 10g1 provided at the tip of the cylinder rod of the X-axis pusher 10g is pressed against the end of the workpiece W in the Y-axis direction and pressed against the pair of X-axis reference blocks 10c that are disposed to face each other. In addition, a pressing member 10h1 provided at the tip of the cylinder rod of the Y-axis pusher 10h is pressed against the end of the workpiece W in the X-axis direction and pressed against the pair of Y-axis reference blocks 10d that are disposed to face each other. Thereby, the workpiece W is aligned in the X-Y direction, and the positional displacement orientation (θ displacement) in the direction of rotation with respect to the preheating stage 10b is adjusted.

### Loader Hand Mechanism

The above workpiece W preheated by the preheating part 10 and aligned is held on the preheating stage 10b by the loader 4 (loader hand mechanism) and conveyed to the mold frame 11a.

As shown in FIG. 5A, the loader 4 includes the loader hand 4b that holds the workpiece W on the preheating stage 10b. The loader hand 4b includes the annular frame 4b1 that presses the outer circumferential part from the upper surface of the workpiece W on the preheating stage 10b and a chuck 4b2 that supports the lower surface of the workpiece W at a plurality of locations by providing a predetermined clearance a with the end of the workpiece.

As described above, the loader 4 suppresses the entire circumference of the workpiece W from the upper surface side to the annular frame 4b1 while the back side of the workpiece is supported by the chuck 4b2 (multi-point chuck) provided at a plurality of locations on one side of the workpiece W, and holds both surfaces of the workpiece in an insertion manner. As shown in FIG. 5A, the pressing force of the frame 4b1 is controlled by the electro-pneumatic regulator 22, the pressing force is variably controlled according to an input signal, and thus warping of the workpiece W that fluctuates due to preheating is minimized. A multi-point chuck 4b2 of the loader 4 is supported by providing a predetermined clearance a with both ends of the workpiece in consideration of expansion and contraction of the workpiece W. That is, in order for the loader 4 to handle the workpiece W (the carrier K) in both states before and after molding, the clearance a is provided so that the workpiece size at room temperature and the workpiece size after molding at a maximum temperature can be handled. Therefore, it is possible to absorb the difference between the external form size of the workpiece W before preheating and the external form size of the workpiece W after preheating. Thereby, the clearance a needs to have a size exceeding the amount of elongation due to heating calculated by the external form size (length) of the workpiece W at room temperature, the difference between the temperature of the workpiece W at room temperature and the temperature of the workpiece after molding, and the coefficient of linear expansion determined according to the material of the workpiece W.

As shown in FIG. 5B, in the loader hand 4b, the imaging camera 4a (position detection unit) is provided. The imaging camera 4a detects a distance (positional displacement) between the external form position (for example, upper left corner) of the workpiece W and the reference position (alignment mark). Specifically, a distance (amount of positional displacement) in the X-Y direction between the corners in which sides on which the X-axis reference block 10c and the Y-axis reference block 10d do not abut intersect and the alignment mark is detected. Thereby, for example, when it is assumed that the distance in the X direction and the Y direction is 10 mm, if the distance in the X direction is 10 mm and the distance in the Y direction is 10 mm, the amount of displacement of the center position of the workpiece W is 0 mm in both the X-Y directions. On the other hand, in this case, when the distance in the X direction is 9 mm and the distance in the Y direction is 9.5 mm, the amount of displacement of the center position of the workpiece W is 0.5 mm in the X direction and 0.25 mm in the Y direction. When such an amount of positional displacement of the workpiece W is aligned according to a configuration to be described below and holding and conveying are then performed, conveying and positioning with respect to the frame can be performed without using positioning holes or the like.

As will be described below, an image processing unit 23 (refer to FIG. 6) including a control unit 25 reads the external form position (coordinates) of the workpiece W disposed on the preheating stage 10b and detects a distance (positional displacement) in the X-Y direction from the alignment mark. An X-Y servo mechanism 24 (alignment mechanism) is provided in the loader 4 so that it can move the loader hand 4b in the X-Y direction. Specifically, a motor gear 24b of an X-axis motor 24a is engaged with an X-axis rack part 4b3 of the loader hand 4b, and a motor gear 24d of a Y-axis motor 24c is engaged with a Y-axis rack part 4b4 of the loader hand 4b. The X-Y servo mechanism 24 aligns a center position O of the loader hand 4b with a center position O of the workpiece W in the X-Y direction according to the amount of positional displacement detected by the imaging camera 4a. The loader 4 conveys the workpiece W that is held with the loader hand 4b to the mold frame 11a. Then, the workpiece W is delivered from the loader hand 4b to the surface of the lower mold clamp in alignment with the lock block provided in the lower mold, and the workpiece W is sucked and held.

Here, one imaging camera 4a is provided in the loader 4, but as shown in FIG. 5C, a plurality of imaging cameras 4a may be provided in the loader hand 4b, and the coordinates of the workpiece W at diagonal positions may be read, positional displacement between a virtual stage center position O1 and a workpiece center position O2 in the X-Y direction may be detected by the image processing unit 23, and the X-Y servo mechanism 24 may be operated to align the loader 4 and the center position O2 of the workpiece W.

Here, a control system of the compression molding device will be described with reference to a block configuration diagram centered on the preheating part 10 and the loader 4. The control unit 25 includes a CPU that controls operations of the compression molding device according to an input signal from a host controller and an input unit 26 such as an operation unit, a ROM in which a control program is stored, a RAM that reads the control program and is used for a work area of the CPU, the image processing unit 23 that reads coordinates from an image captured by the imaging camera 4a and calculates an amount of positional displacement, and the like. From the control unit 25, an output command is sent to the preheater 10a, the X-axis pusher 10g, the Y-axis pusher 10h, and the vacuum generating device 21 provided in the preheating part 10, and an output command is sent to the electro-pneumatic regulator 22, the X-Y servo mechanism 24 and the like provided in the loader 4, and operations of respective units are controlled.

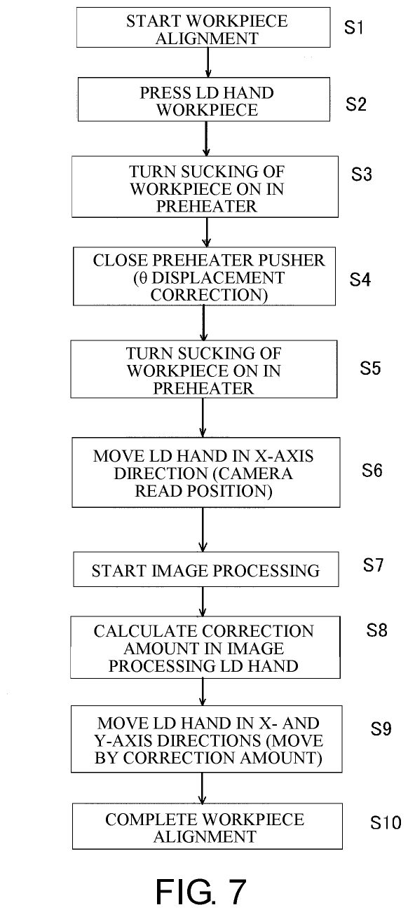

Here, an example of a workpiece alignment operation using the preheating part 10 and the loader 4 will be described with reference to a flowchart shown in FIG. 7.

When the loader 4 receives the workpiece W on which the resin R is mounted from the workpiece transfer part 2 at the delivery position Q on the workpiece delivery unit C shown in FIG. 1, and the loader 4 conveys on the preheating stage 10b, the workpiece alignment operation starts (Step S1).

When the loader 4 reaches the preheating stage 10b, the loader hand (LD hand) 4b descends and presses the workpiece W against the preheating stage 10b (Step S2). In this case, in order to correct deflection of the workpiece W and prevent a gap between it and the stage from being formed, the electro-pneumatic regulator 22 may perform control so that the pressing force of the frame 4b1 increases. This is to increase thermal conductivity of the workpiece W during preheating.

Next, the vacuum generating device 21 is started, adsorbs the workpiece W through the suction hole 10f of the preheating stage 10b and sucks it onto the preheating stage 10b, and the preheater 10a is started and preheats the workpiece W and the resin R to a predetermined temperature (for example, 100° C.) (Step S3: refer to FIGS. 4A and 4B).

When the workpiece W and the resin R are preheated, suction is weakened (vacuum broken) by the vacuum generating device 21, as shown in FIG. 4A, the X-axis pusher 10g is operated, the pressing member 10g1 provided at the tip of the cylinder rod pushes the end of the workpiece W in the Y-axis direction and presses against the pair of X-axis reference blocks 10c that are disposed to face each other. In addition, the Y-axis pusher 10h is operated, the pressing member 10h1 provided at the tip of the cylinder rod pushes the end of the workpiece W in the X-axis direction and presses against the pair of Y-axis reference blocks 10d that are disposed to face each other. Thereby, the workpiece W is aligned in the direction of rotation with respect to the preheating stage 10b (θ displacement correction: Step S4).

When the alignment operation of the workpiece W is completed, the vacuum generating device 21 is started again, adsorbs the workpiece W through the suction hole 10f of the preheating stage 10b and sucks it onto the preheating stage 10b, and the preheater 10a is started and preheats the workpiece W and the resin R to a predetermined temperature (for example, 100° C.) (Step S5).

Next, the imaging camera 4a mounted on the loader hand 4b moves the loader hand 4b in the X-axis direction and captures an external form image of the upper left corner of the workpiece W and an alignment mark image (Step S6: refer to FIG. 5B). The image processing unit 23 provided in the control unit 25 starts image processing from the captured images (Step S7), and calculates an amount of positional displacement (correction amount) of the workpiece W in the X-Y direction (Step S8).

According to the amount of positional displacement of the workpiece W in the X-Y direction calculated by the image processing unit 23, the control unit 25 controls driving of the X-axis motor 24a and the Y-axis motor 24c according to the X-Y servo mechanism 24 via a motor driver (refer to FIG. 5B) and moves the loader hand 4b in the X-Y direction, and aligns the center position O of the loader hand 4b with the center position O of the workpiece W (Step S9). Then, complete workpiece alignment (Step S10).

Then, the loader hand 4b descends onto the preheating stage 10b and suppresses the entire circumference of the workpiece W from the upper surface side with the annular frame 4b1 while the back side of the workpiece is supported by the chuck 4b2 (multi-point chuck) provided at a plurality of locations on one side of the workpiece W, and holds both surfaces of the workpiece in an insertion manner (refer to FIG. 5A). As shown in FIG. 1, when the loader hand 4b holding the workpiece W is elevated, the loader 4 moves from above the preheating stage 10b to the mold frame 11a and loads the workpiece W into the lower mold.

With the above configuration, when the loader 4 (loader hand mechanism) holds the workpiece W aligned by the preheating part 10 (workpiece alignment part), since the center position of the loader hand 4b is aligned with the center position of the workpiece W and held according to the amount of positional displacement in the X-Y direction between the external form position of the workpiece W and the reference position (alignment mark), it is possible to hold the thin and large-size workpiece W without positional displacement.

Even if the workpiece W is preheated on the preheating stage 10b and the amount of warpage of the workpiece W differs, the flatness of the workpiece W can be maintained by changing the pressing force of the frame 4b1, and the external form size of the workpiece W can be accurately detected and the workpiece W can be accurately positioned and held while maintaining the flatness of the workpiece W with the loader hand 4b.

As the mold frame 11a of the present example, the upper mold cavity type has been described, but a lower mold cavity type mold frame may be used. In this case, the workpiece W may be mounted on the holder plate 5 with a surface on which an electronic component is mounted downward, and may be transferred by the workpiece transfer part 2.

In addition, the workpiece W is supplied to the upper mold by the loader 4 and the resin supply unit B may directly supply the mold resin R (granular resin or liquid resin) into the lower mold cavity by the dispenser and may supply the mold resin R that is disposed on the release film F.

In addition, the preheating part 10 has been exemplified as the workpiece alignment part and the loader 4 has been exemplified as the loader hand mechanism, but the present invention is not limited thereto, and the resin supply stage 7 on which the workpiece W is disposed, the pick and place mechanism 8 that picks up and conveys the workpiece W, and the like may be applied.

It will be apparent to those skilled in the art that various modifications and variations can be made to the disclosed embodiments without departing from the scope or spirit of the present invention. In view of the foregoing, it is intended that the present invention covers modifications and variations provided that they fall within the scope of the following claims and their equivalents.

What is claimed is:

1. A resin molding device in which a workpiece in which an electronic component is mounted on a carrier is conveyed to a mold frame and molded with a resin, comprising:
a workpiece alignment part that adjusts the orientation of the workpiece held on a stage to a reference position; and
a loader hand mechanism that holds the workpiece aligned by the workpiece alignment part and conveys it to the mold frame,
wherein the loader hand mechanism comprises:
a loader hand that holds and clamps the workpiece on the stage;
a position detection unit that detects positional displacement between an external form position of the workpiece provided in the loader hand and the reference position; and
an alignment mechanism that aligns a center position of the loader hand with a center position of the workpiece in the X-Y direction according to an amount of positional displacement detected by the position detection unit.

2. The resin molding device according to claim 1, wherein the workpiece alignment part presses the workpiece against reference blocks provided in the X-Y direction and adjusts the orientation of the workpiece to the reference position.

3. The resin molding device according to claim 1, wherein the position detection unit comprises an imaging camera, reads coordinates of the external form of the workpiece disposed on the stage, and detects positional displacement in the X-Y direction from a positioning mark indicating the reference position.

4. The resin molding device according to claim 1, wherein the position detection unit comprises a plurality of imaging cameras, detects coordinates at diagonal positions of the external form of the workpiece, and detects positional displacement in the X-Y direction from a virtual stage center position.

5. The resin molding device according to claim 1, wherein the stage is a preheating stage that preheats the workpiece.

6. The resin molding device according to claim 5, wherein the loader hand comprises:
an annular pressing member that presses an outer circumferential part from an upper surface of the workpiece; and
a chuck that supports a lower surface of the workpiece with a predetermined clearance with the end of the workpiece, and
wherein the pressing member is controlled so that a pressing force of the workpiece is variable, and the loader hand mechanism conveys the workpiece preheated on the preheating stage, which is clamped between the pressing member and the chuck, to the mold frame.
